(19) United States
(12) Patent Application Publication
(10) Pub. No.: US 2026/0114237 A1
(43) Pub. Date: Apr. 23, 2026

(54) LIFT AND ROTATE ASSEMBLES, CHAMBER ARRANGEMENTS AND SEMICONDUCTOR PROCESSING SYSTEMS INCLUDING LIFT AND ROTATE ASSEMBLIES, AND METHODS OF MAKING LIFT AND ROTATE ASSEMBLIES AND DEPOSITING MATERIAL LAYERS USING LIFT AND ROTATE ASSEMBLIES

(71) Applicant: ASM IP Holding B.V., Almere (NL)

(72) Inventors: Bradley Wayne Evans, Apache Junction, AZ (US); Shujin Huang, Phoenix, AZ (US); Yu-Jung Chen, Scottsdale, AZ (US); Jingcheng Zhou, Tempe, AZ (US); Partha Sarathy Reddy Kudala, Tempe, AZ (US); Fan Gao, Chandler, AZ (US)

(21) Appl. No.: 19/359,839

(22) Filed: Oct. 16, 2025

Related U.S. Application Data
(60) Provisional application No. 63/709,235, filed on Oct. 18, 2024.

(51) Int. Cl. H01L 21/687; C23C 16/458

(52) U.S. Cl. CPC H10P 72/7626; C23C 16/4584

(57) ABSTRACT

A lift and rotate assembly includes a shaft carrier, a ceramic shaft, a segmented sleeve, and a flanged sleeve. The shaft carrier defines a bore therethrough, the ceramic shaft is received within the bore of the shaft carrier, the segmented sleeve is seated in the shaft carrier and extends about the ceramic shaft, and the flanged sleeve defines a rotation axis and threadedly receives therein the shaft carrier. The segmented sleeve is compressively fixed and radially collapsed about the ceramic shaft within bore of the shaft carrier to limit tilt and wobble of a substrate support carried by the ceramic shaft during rotation about the rotation axis. Chamber arrangements and semiconductor processing systems including lift and rotate assemblies, methods of making lift and rotate assemblies, and methods of depositing material layers using lift and rotate assemblies are also described.

### CROSS-REFERENCE TO RELATED APPLICATIONS

This application is a nonprovisional of, and claims priority to and the benefit of, U.S. Provisional Patent Application No. 63/709,235 , filed Oct. 18, 2024, which is hereby incorporated by reference herein.

### FIELD OF INVENTION

The present disclosure generally relates to rotating machinery, and more particularly to controlling rotation of rotating structures in rotating machines.

### BACKGROUND OF THE DISCLOSURE

Rotation is commonly transmitted in rotating machinery between rotation a source and a rotated structure. The rotated structure is generally coupled to the rotation source by one or more transmission component, such as an intervening pulley and belt or gearbox, such that the rotated structure rotates about a desired rotary axis using rotation communicated through the one or more transmission component. In some rotating machines rotation of the rotating structure and/or the intervening one or more transmission component is controlled, such as to limit wobble and runout of the rotated structure about the rotation axis, to limit the affect that runout and wobble can otherwise have on operation of the rotating machine. For example, alignment of the one or more transmission component relative to the rotation axis may be controlled using compressible structures such as O-rings, x-rings, and quad rings.

Such systems and methods have generally been acceptable for their intended purpose. However, there remains a need in the art for improved drive assemblies, chamber arrangement and semiconductor processing systems including drive assembles, and methods of making drive assemblies and depositing material layers using drive assemblies using drive assemblies. The present disclosure provides a solution to this need.

### SUMMARY OF THE DISCLOSURE

A lift and rotate assembly includes a shaft carrier, a ceramic shaft, a segmented sleeve, and a flanged sleeve. The shaft carrier defines a bore therethrough, the ceramic shaft is received within the bore of the shaft carrier, the segmented sleeve is seated in the shaft carrier and extends about the ceramic shaft, and the flanged sleeve defines a rotation axis and threadedly receives therein the shaft carrier. The segmented sleeve is compressively fixed and radially collapsed about the ceramic shaft within bore of the shaft carrier to limit tilt and wobble of a substrate support carried by the ceramic shaft during rotation about the rotation axis.

In addition to one or more of the features described above, or as an alternative, further examples of the lift and rotate assembly may include that the shaft carrier defines a bore therethrough. The bore may have a tapered segment and a shoulder defined therein. A first end of the ceramic shaft may be axially spaced apart from the shoulder within the bore.

In addition to one or more of the features described above, or as an alternative, further examples of the lift and rotate assembly may include an inner resilient member axially separating the ceramic shaft from the shoulder. The inner resilient member may be captive between the first end of the ceramic shaft and the shoulder.

In addition to one or more of the features described above, or as an alternative, further examples of the lift and rotate assembly may include that the shaft carrier defines a first male threaded segment and a second male threaded segment on an exterior surface of the shaft carrier. The first male threaded segment may axially separate the second male threaded segment from the first male threaded segment. The second male threaded segment may be defined on the exterior surface of the shaft carrier at a location radially between the first male threaded segment and the rotation axis.

In addition to one or more of the features described above, or as an alternative, further examples of the lift and rotate assembly may include that the ceramic shaft is formed from one of fused silica, quartz, and sapphire.

In addition to one or more of the features described above, or as an alternative, further examples of the lift and rotate assembly may include that the ceramic shaft defines a bore therethrough. A probe member may be slidably received within the bore and protrude from either (or both) the first end and the second end of the ceramic shaft.

In addition to one or more of the features described above, or as an alternative, further examples of the lift and rotate assembly may include that the ceramic shaft is radially spaced apart from the shaft carrier within the bore defined within the shaft carrier. The ceramic shaft is axially spaced apart from a shoulder defined within the bore of the shaft carrier.

In addition to one or more of the features described above, or as an alternative, further examples of the lift and rotate assembly may include that the segmented sleeve has a minor tapered portion and a major tapered portion. The minor tapered portion of the segmented sleeve may be received (e.g., fixed) within shaft carrier. The major tapered portion of the segmented sleeve may protrude axially from the shaft carrier.

In addition to one or more of the features described above, or as an alternative, further examples of the lift and rotate assembly may include the minor tapered portion of the segmented sleeve has a nominal taper angle that is different than taper of a bore defined within the shaft carrier to collapse the segmented sleeve to a width greater than that of the ceramic shaft. The major tapered portion of the segmented sleeve may have a nominal tapered angle that is different than taper of a bore defined within the flanged sleeve to further collapse the segment sleeve to a width substantially equivalent to that of the ceramic shaft.

In addition to one or more of the features described above, or as an alternative, further examples of the lift and rotate assembly may include that the segmented sleeve defines a circumferential slot extending about the segmented sleeve. The circumferential slot may axially separating the minor tapered portion of the segmented sleeve from the major tapered portion of the segmented sleeve. The shaft carrier may have a flange portion protruding radially inward and occupying, only in part, the circumferential slot extending about the segmented sleeve.

In addition to one or more of the features described above, or as an alternative, further examples of the lift and rotate assembly may include that the segmented sleeve conforms conform to a nominal size ER 20 collet as described in ISO Standard No. 15488:2003(E).

In addition to one or more of the features described above, or as an alternative, further examples of the lift and rotate assembly may include that the segmented sleeve defines a bore therethrough. The bore may be diametrically enlarged relative the nominal size ER 20 collet as described in ISO Standard No. 15488:2003(E).

In addition to one or more of the features described above, or as an alternative, further examples of the lift and rotate assembly may include that the segmented sleeve is formed from DIN 1.4122 stainless steel. A fluid selected from the group consisting of phosphine (P₂H₄), arsine (AsH₃), hydrogen (H₂) gas, and hydrochloric (HCl) acid contacting the segmented sleeve, the DIN 1.4122 limiting (or eliminating) corrosion of the segmented sleeve otherwise associated with contact by the fluid.

In addition to one or more of the features described above, or as an alternative, further examples of the lift and rotate assembly may include that the flanged sleeve has a stem portion, an axially opposite flange portion, and stepped or necked portion axially intermediate the stem portion and the flange portion of the flanged sleeve.

In addition to one or more of the features described above, or as an alternative, further examples of the lift and rotate assembly may include that the flanged sleeve defines a bore therethrough having a tapered segment and a fixed width segment. The stem portion of the flanged sleeve may radially overlap the tapered segment of the bore defined within the flanged sleeve. The flange portion of the flanged sleeve may radially overlaps the fixed width segment of the bore defined within the flanged sleeve. The major tapered portion of the segmented sleeve may be compressively seated within the tapered segment of the bore defined within the flanged sleeve.

In addition to one or more of the features described above, or as an alternative, further examples of the lift and rotate assembly may include that a cylindrical sleeve threadedly received about the shaft carrier and arranged at least in part within a bore defined within the flange portion of the flanged sleeve.

In addition to one or more of the features described above, or as an alternative, further examples of the lift and rotate assembly may include a flag structure and a drive gear. The flag structure may extend about the stem portion of the flanged sleeve. The drive gear may extend about the stem portion and be fastened to the flange portion of the flanged sleeve. The flag structure may be axially intermediate the drive gear and the flange portion of the flanged sleeve.

In addition to one or more of the features described above, or as an alternative, further examples of the lift and rotate assembly may include a bearing arrangement and a drive gear. The bearing arrangement may include a rotor extending about the stem portion of the flanged sleeve; and fastened to the flange portion of the flanged sleeve, a stator extending about the rotor and coupled thereto by a bearing body, and a ferrofluidic seal intermediate the stator and the rotor fluidly separating the ceramic shaft from an environment external to the lift and rotate assembly. The stator and the rotor of the bearing arrangement may radially overlap the shaft carrier. The drive gear may extend about the stator and be fastened to the flange portion of the flanged sleeve.

In addition to one or more of the features described above, or as an alternative, further examples of the lift and rotate assembly may include that the shaft carrier has a castellated face protruding from the flanged sleeve. The lift and rotate assembly may further include a cylindrical sleeve extending about the shaft carrier and having a castellated face protruding from the flanged sleeve. The castellated face of the cylindrical sleeve may extend about the castellated face of the shaft carrier. The cylindrical sleeve may be rotationally free relative to the shaft carrier.

A semiconductor processing system is provided. The semiconductor processing includes a chamber arrangement and a dopant-containing precursor source. The chamber arrangement includes a chamber body with a tubulation member protruding therefrom, an injection flange abutting an injection end of the chamber body and a substrate support supported for rotation within a interior of the chamber body by a lift and rotate assembly as described above. The ceramic shaft extends through the tubulation member and carrying the substrate support. The dopant-containing precursor source coupled to the injection flange by both a supply conduit and the tubulation member by a dopant-containing precursor source-to-tubulation member conduit.

A method of making a lift and rotate assembly is provided. The method includes seating an inner resilient member on a shoulder in a bore defined within a shaft carrier, seating a minor tapered portion of a segmented sleeve in a tapered segment of the bore defined within the shaft carrier, and seating a first end of a ceramic shaft in the bore and on the inner resilient member seated on the shoulder and within bore. The shaft carrier may be threadedly seated in a bore defined within a flanged carrier such that the ceramic shaft protrudes from the shaft carrier along a rotation axis defined by the flanged sleeve, seating of the segmented sleeve in the shaft carrier collapsing the segmented sleeve, threadedly fixing the shaft carrier in the bore further collapsing the segmented sleeve such the segmented sleeve is compressively fixed and radially collapsed about the ceramic shaft within the bore of the shaft carrier to limit tilt and wobble of a substrate support carried by the ceramic shaft during rotation about the rotation axis.

A material layer deposition method is provided. The method includes, at a lift and rotate assembly as described above, seating a substrate on a substrate support carried by the ceramic shaft, rotating the substrate support about the rotation axis, and contacting the substrate with a process fluid to at least one of deposit a material layer onto the substrate and remove material from the substrate. Tilt and wobble of the substrate support carried by the ceramic shaft during rotation about the rotation axis is limited by compressive fixation and radial collapse of the segmented sleeve about the ceramic shaft.

A tilt and wobble kit for a lift and rotate assembly is provided. The kit includes a shaft carrier configured to seat therein a ceramic shaft, a segmented sleeve configured to seat within the shaft carrier and about the ceramic shaft, and a flanged sleeve having a bore configured to receive therein the segmented sleeve and the shaft carrier to collapse the segmented sleeve about the ceramic shaft to limit tilt and wobble of the ceramic shaft during rotation about a rotation axis defined by the flanged sleeve.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a lift and rotate assembly in accordance with the present disclosure, schematically showing the lift and rotate assembly operably coupled to a substrate support supported within a chamber arrangement of the semiconductor processing system;

FIG. 2 is a schematic view of the semiconductor processing system of FIG. 1 according to an example, schematically showing a chamber arrangement operably associated with the controller and coupling a fluid source to an exhaust source;

FIG. 3 is a cross-sectional side view of the chamber arrangement of FIG. 1 according to an example of the present disclosure, schematically showing the lift and rotate module coupled to the substrate support by a ceramic shaft within a tubulation member;

FIG. 4 is a perspective view of a lift and rotate assembly according to an example of the present disclosure;

FIG. 5 is an exploded view of the lift and rotate assembly of FIG. 4 according to an example of the disclosure, showing a ceramic shaft and a segmented sleeve exploded away from shaft carrier and a flanged sleeve;

FIG. 6 is an isometric view of the segmented sleeve included in the lift and rotate module according to an example of the present disclosure, showing a bore defined through the sleeve member and nominal taper angles of major and minor tapered portions of the sleeve member;

FIG. 7 is a cross-sectional side view of a lift and rotate assembly according to an example of the disclosure, showing the flanged sleeve cooperating with the shaft carrier to collapse the segmented sleeve and thereby fix of the ceramic shaft relative to the shaft carrier for rotation about a rotation axis;

FIG. 8 and FIG. 9 are a block diagram of a method of making a lift and rotate assembly for a semiconductor processing system in accordance with an example of the disclosure, showing operations of the method according a non-limiting example of the disclosure; and

FIG. 10 is a block diagram of a method of depositing a material layer onto a substrate using a drive assembly in accordance with an example of the disclosure, showing operation of the method according to an illustrative and non-limiting example of the disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

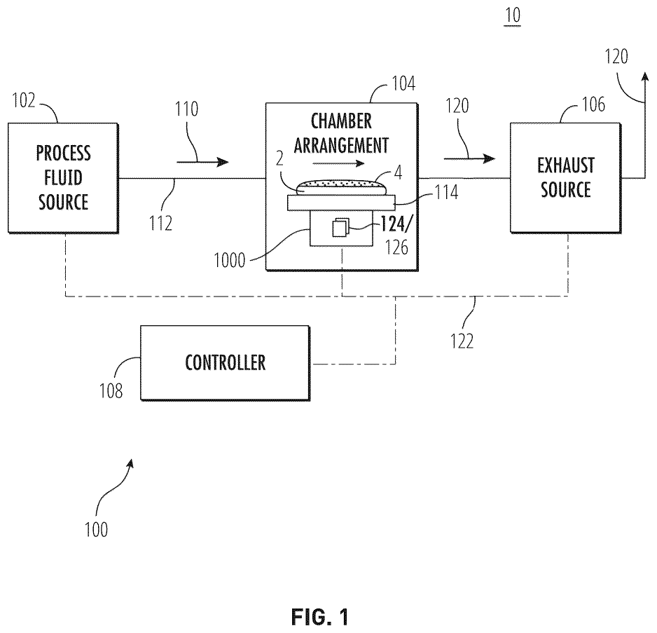

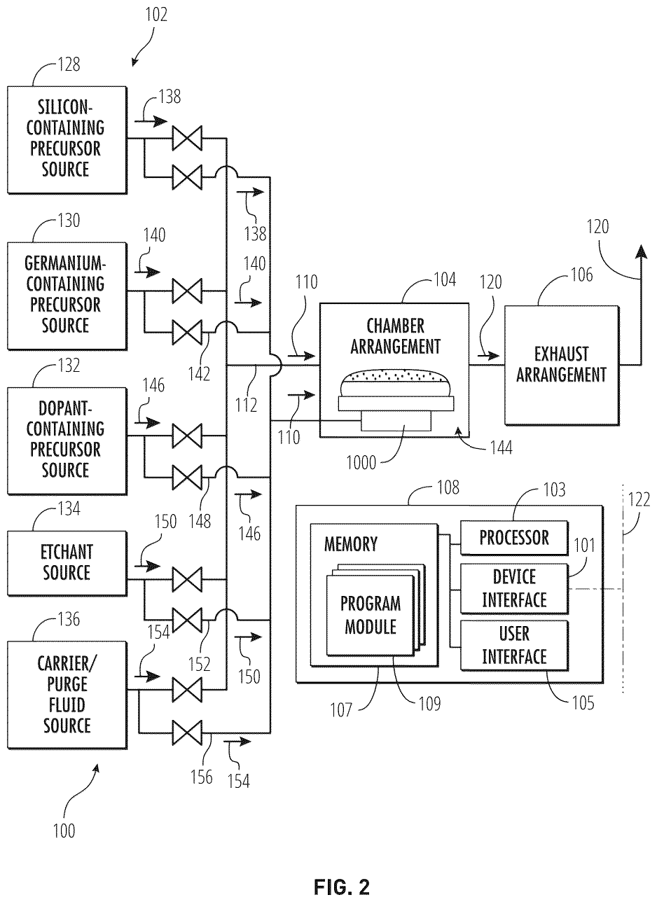

Reference will now be made to the drawings wherein like reference numerals identify similar structural features or aspects of the subject disclosure. For purposes of explanation and illustration, and not limitation, a partial view of an example of a lift and rotate assembly in accordance with the present disclosure is shown in FIG. 1 and is designated generally by reference character 1000. Other examples of lift and rotate assemblies, chamber arrangements and semiconductor processing systems including lift and rotate assemblies, and related methods of making lift and rotate assemblies and depositing material layers onto substrates using lift and rotate assemblies in accordance with the present disclosure, or aspects thereof, are provided in FIG. 2 to FIG. 10, as will be described. The systems and methods of the present disclosure may be used to rotate substrates in chamber arrangements of semiconductor processing systems, such as during the deposition of silicon-containing epitaxial material layers onto substrates using chemical vapor deposition (CVD) techniques and/or the removal of material from substrates using etching techniques, though the present disclosure is not limited to material layer deposition or material removal operation or to semiconductor device fabrication in general.

With reference to FIG. 1, a semiconductor processing system 100 is shown. The semiconductor processing system 100 includes a process fluid source 102, a chamber arrangement 104 including the lift and rotate assembly 1000, an exhaust source 106, and a controller 108. The process fluid source 102 includes a process fluid 110, is connected to the chamber arrangement 104 by a supply conduit 112, and is configured to communicate a flow of the process fluid 110 to the chamber arrangement 104. The chamber arrangement 104 includes a substrate support 114 (e.g., a susceptor structure) supported for rotation about a rotation axis 116 and operably associated with the lift and rotate assembly 1000, is fluidly coupled to the process fluid source 102 by the supply conduit 112, and is configured to contact a substrate 2 seated on the substrate support 114 under conditions (e.g., temperature and pressure) selected to cause a material layer 4 to deposit onto the substrate 2 and/or material to be removed from the substrate 2. The exhaust source 106 is connected to the chamber arrangement 104 by an exhaust conduit 118, is in fluid communication with an external environment 10 outside of the semiconductor processing system 100, and is configured to communicate a flow of residual process fluid and/or reaction products 120 issued by the chamber arrangement 104 to the external environment 10. It is contemplated that the controller 108 be operably connected to the lift and rotate assembly 1000, for example through a wired or wireless link 122, and is configured to at least one or rotate R the substrate support 114 about the rotation axis 116 and seat and unseat the substrate 2 from the substrate support using a rotation source 124 and an actuator 126 included in the lift and rotate assembly 1000.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the process fluid source 102 is shown according to an example of the present disclosure. In the illustrated example the process fluid source 102 includes a silicon-containing precursor source 128, a germanium-containing precursor source 130, a dopant-containing precursor source 132, an etchant source 134, and a carrier/purge fluid source 136. The silicon-containing precursor source 128 includes a silicon-containing material layer precursor 138, is coupled to the supply conduit 112, and is configured to communicate a flow of the silicon-containing material layer precursor 138 to the chamber arrangement 104 through the supply conduit 112. In this respect it is contemplated that the silicon-containing precursor source 128 may be coupled to the supply conduit 112 by a flow control device, such as metering valve and/or a mass flow controller (MFC) device, and that the flow control device may be operably associated with the controller 108 to provide the flow of the silicon-containing material layer precursor 138 to the chamber arrangement 104. In certain examples the silicon-containing material layer precursor 138 may include (or consist of or consist essentially of) a non-halogenated silicon-containing precursor. Examples of suitable non-halogenated silicon-containing precursors include silane (SiH₄), disilane (Si₂H₆), and trisilane (H₂Si(SiH₃)₂). In accordance with certain examples, the silicon-containing material layer precursor 138 may include (or consist of or consist essentially of) a halogenated silicon-containing precursor. Non-limiting examples of halogenated silicon-containing precursors include dichlorosilane (H₂SiCl₂), trichlorosilane(HCl₃Si), and higher order chlorinated silicon-containing precursors. It is also contemplated that the silicon-containing precursor source may be configured to provide two or more silicon-containing precursors to the chamber arrangement 104 and remain within the scope of the present disclosure.

The germanium-containing precursor source 130 is similar to the silicon-containing precursor source 128 and additionally includes a germanium-containing material layer precursor 140. In this respect it is contemplated that the germanium-containing precursor source 130 be connected to the supply conduit 112, for example through an MFC device operably associated with the controller 108, and be configured to communicate a flow of the germanium-containing material layer precursor 140 to the chamber arrangement 104. In certain examples the germanium-containing precursor source 130 may further be connected to the chamber arrangement 104 through the lift and rotate assembly 1000, for example through a germanium source-to-tubulation member supply conduit 142 fluidly coupled to an interior 144 of the chamber arrangement 104 by the lift and rotate assembly 1000, the germanium source-to-tubulation member supply conduit 142 extending fluidly in parallel with the supply conduit 112 between the germanium-containing precursor source 130 and the chamber arrangement 104. In accordance with certain examples, the germanium-containing material layer precursor 140 may include germane (GeH₄). Although shown and described herein as including that the germanium-containing material layer precursor 140, it is to be understood and appreciated that another alloying material layer precursor including another metal may be employed, such as gallium (Ga) and or aluminum (Al)-containing precursors, and remain within the scope of the present disclosure.

The dopant-containing precursor source 132 is similar to the silicon-containing precursor source 128 and additionally includes a dopant-containing material layer precursor 146. In this respect the dopant-containing precursor source 132 may be connected to the supply conduit 112, for example through an MFC device operably associated with the controller 108, and be configured to communicate a flow of the dopant-containing material layer precursor 146 to the chamber arrangement 104. In certain examples the dopant-containing precursor source 132 may be further connected to the chamber arrangement 104 through the lift and rotate assembly 1000, for example through a dopant source-to-tubulation member supply conduit 148 fluidly coupled to the interior 144 of the chamber arrangement 104 by the lift and rotate assembly 1000, the dopant source-to-tubulation member supply conduit 148 extending fluidly in parallel with the supply conduit 112 between the dopant-containing precursor source 132 and the chamber arrangement 104. In accordance with certain examples, the dopant-containing material layer precursor 146 may include p-type dopant-containing precursor or an n-type dopant-containing precursor. Examples of suitable n-type dopants include phosphorous (P) and arsenic (As), which may be communicated to the chamber arrangement 104 by flowing phosphine (P₂H₄) and/or arsine (AsH₃) through either (or both) the supply conduit 112 and the dopant source-to-tubulation member supply conduit 148 using the dopant-containing precursor source 132. Examples of suitable p-type dopants include boron (B), which may be communicated to the chamber arrangement 104 by flowing diborane (B₂H₆) through either (or both) the supply conduit 112 and the dopant source-to-tubulation member supply conduit 148 using the dopant-containing precursor source 132. As will be appreciated by those of skill in the art in view of the present disclosure, other dopant-containing material layer precursors may be included in the dopant-containing material layer precursor 146 and remain within the scope of the present disclosure.

The etchant source 134 may also be similar to the silicon-containing precursor source 128 and additionally include an etchant 150. In this respect it is contemplated that the etchant source 134 may be connected to the chamber arrangement 104 by the supply conduit 112, for example through a flow control device like a metering valve or an MFC device, to provide a flow of the etchant 150 to the chamber arrangement 104. The etchant source 134 may further be connected to the chamber arrangement 104 through the lift and rotate assembly 1000, for example through an etchant source-to-tubulation member supply conduit 152, which may couple the etchant source 134 to the interior 144 of the chamber arrangement 104 fluidly in parallel with the supply conduit 112. In certain examples the etchant 150 may include a halogen-containing etchant, such as a chlorine (Cl) or fluorine (F) containing etchant. Examples of suitable chlorine-containing etchants include chlorine (Cl₂) gas and hydrochloric (HCl) acid; examples of suitable fluorine-containing etchants include hydrofluoric (HF) acid. As will be appreciated by those of skill in the art in view of the present disclosure, other etchants may be employed and remain within the scope of the present disclosure.

The carrier/purge fluid source 136 may be similar to the silicon-containing precursor source 128 and additionally include a carrier/purge fluid 154. In this respect it is contemplated that the carrier/purge fluid source 136 may be connected to the chamber arrangement 104 by the supply conduit 112, for example through a flow control device like a metering valve or an MFC device, to provide a flow of the carrier/purge fluid 154 to the chamber arrangement 104. The carrier/purge fluid source 136 may further be connected to the chamber arrangement 104 through the lift and rotate assembly 1000, for example through an carrier/purge fluid-to-tubulation supply conduit 156, which may couple the carrier/purge fluid source 136 to the interior 144 of the chamber arrangement 104 fluidly in parallel with the supply conduit 112. In certain examples the carrier/purge fluid 154 may include (or consist of or consist essentially of) hydrogen (H₂) gas. In accordance with certain examples, the carrier/purge fluid 154 may include an inert fluid. Examples of suitable inert fluids include nitrogen (N₂) gas as well as noble gases such as argon (Ar), krypton (Kr), helium (He), as well as mixtures including one or more of the aforementioned fluids. As will be appreciated by those of the skill in the art in view of the present disclosure, the carrier/purge fluid source 136 may further be configured to intermix the carrier/purge fluid 154 with one or more of the silicon-containing material layer precursor 138, the germanium-containing material layer precursor 140, the dopant-containing material layer precursor 146, and or the etchant 150 for provision the interior 144 of the chamber arrangement 104 as a mixture, for example through either (or both) the supply conduit 112 and the lift and rotate assembly 1000. As will also be appreciated by those of skill in the art in view of the present disclosure, one or more of aforementioned fluids may be provided to the chamber arrangement 104 as a gas, the chamber arrangement 104 being a gas phase reactor in such examples.

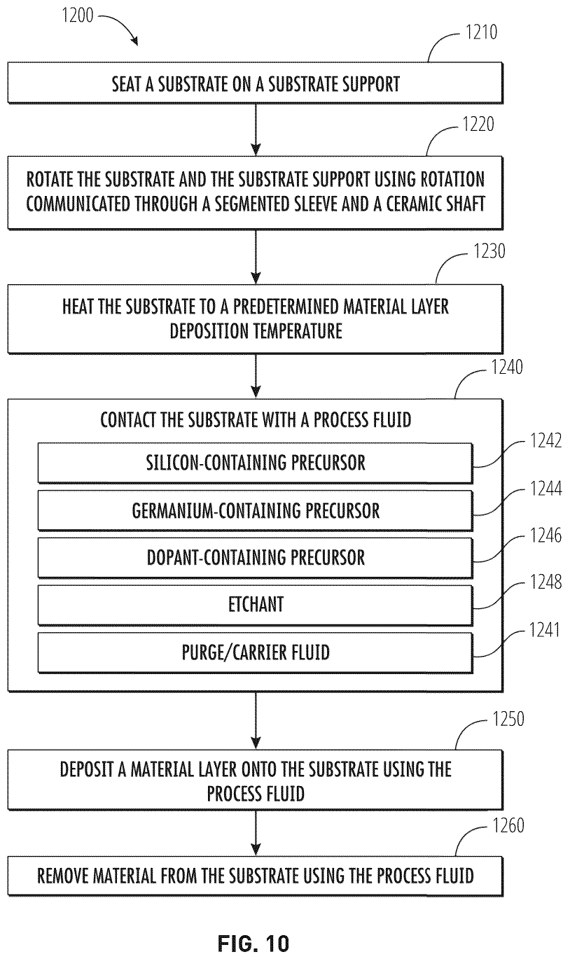

In the illustrated example the controller 108 includes device interface 101, a processor 103, a user interface 105, and a memory 107. The device interface 101 couples the controller 108 to one or more of the process fluid source 102, the chamber arrangement 104, and exhaust source 106, for example through the wired or wireless link 122. The processor 103 is coupled to the device interface 101, is operably associated with the user interface 105 (e.g., to receive user input and/or provide user output therethrough), and is disposed in communication with the memory 107. The memory 107 has plurality of program modules 109 recorded thereon containing instructions that, when read by the processor 103, cause the processor 103 to execute certain operations. Among the operations are operations of a material layer deposition method 1200 (shown in FIG. 10), as will be described. Although shown and described herein as including certain elements and having a specific arrangement, it is to be understood and appreciated that the controller 108 may include additional elements and/or exclude elements shown and described herein, as well as have a different arrangement (e.g., a distributed computing architecture), in other examples and remain within the scope of the present disclosure.

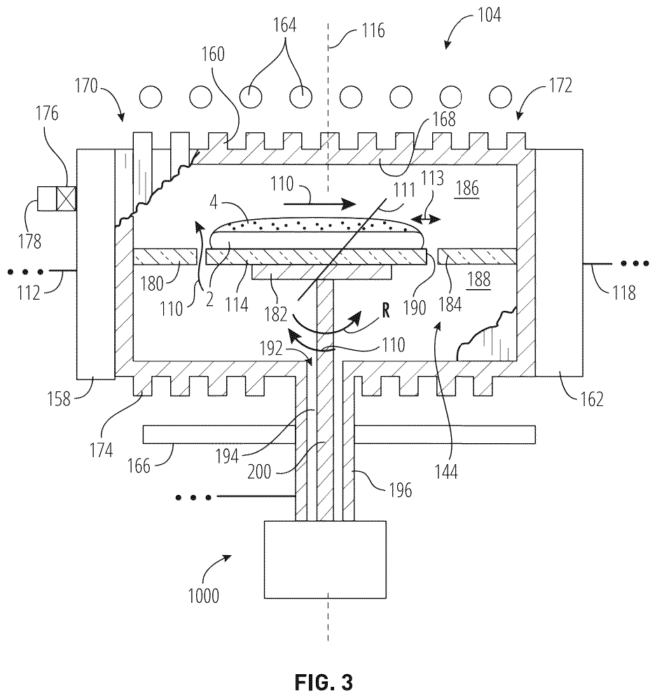

With reference to FIG. 3, the chamber arrangement 104 is shown according to an example of the present disclosure. In the illustrated example the chamber arrangement 104 includes an injection flange 158, a chamber body 160, an exhaust flange 162, an upper heater element array 164, a lower heater element array 166, and the lift and rotate assembly 1000. The chamber body 160 is formed from a ceramic material 168 (e.g., a material transparent to electromagnetic radiation in an infrared waveband), such as fused silica or quartz, and extends between an injection end 170 and a longitudinally opposite exhaust end 172 of the chamber body 160. The injection flange 158 abuts the injection end 170 of the chamber body 160 and fluidly couples the supply conduit 112 to the interior 144 of the chamber body 160. The exhaust flange 162 abuts the exhaust end 172 of the chamber body 160, is fluidly coupled to the injection flange 158 by the interior 144 of the chamber body 160, and is further fluidly coupled to the exhaust source 106 (shown in FIG. 1) by the exhaust conduit 118. In certain examples the chamber body 160 may having a plurality of external ribs 174. The plurality of external ribs 174 may extend laterally about an external surface of the chamber body 160. The plurality of external ribs 174 may further be longitudinally spaced apart from the one another between the injection end 170 and the exhaust end 172 of the chamber body 160. In accordance with certain examples, the chamber body 160 may be ribless, the chamber body 160 having no external ribs between the injection end 170 and the exhaust end 172 of the chamber body 160. It is also contemplated that the chamber body 160 may have an arcuate or dome-like profile and remain within the scope of the disclosure.

The upper heater element array 164 includes a plurality of heater elements configured communicatee radiant heat into the interior 144 of the chamber body 160. In this respect it is contemplated that the upper heater element array 164 may include a plurality of lamps supported above the chamber body 160 and optically coupled the interior 144 of the chamber body 160 by the ceramic material 168 forming the chamber body 160, for example by generating electromagnetic radiation within an infrared waveband for communication into the interior 144 of the chamber body 160. In certain examples, the upper heater element array 164 may include a plurality of linear filament-type lamps supported above the chamber body 160. The plurality of linear filament-type lamps may extend laterally between laterally opposite sidewalls of the chamber body 160 and be longitudinally spaced apart from one another between the injection end 170 and the exhaust end 172 of the chamber body 160 in such examples. In accordance with certain examples, the upper heater element array 164 may include a plurality of linear filament-type lamps extending longitudinally between the injection end 170 and the exhaust end 172 of the chamber body 160. The plurality of linear filament-type lamps may be laterally spaced apart from one another between laterally opposite sidewalls of the chamber body 160 in such examples. It is also contemplated that the upper heater element array 164 may include a plurality of bulb-type lamps supported above the chamber body 160 and remain within the scope of the present disclosure. It is contemplated that the lower heater element array 166 may be similar to the upper heater element array 164 and additionally supported below the chamber body 160 to communicate radiant heat into the interior 144 of the chamber body 160 through the ceramic material 168 forming a lower wall of the chamber body 160.

In certain examples the chamber arrangement 104 may also include a gate valve 176 and substrate transfer robot 178. The gate valve 176 may be coupled to the injection flange 158 and configured to provide communication between the interior 144 of the chamber body 160 and the external environment 10 outside of the chamber arrangement 104 to facilitate loading and unloading substrates, for example the substrate 2, from within the interior 144 of the chamber body 160 prior to and subsequent to deposition of material layers, e.g., the material layer 4, onto substrates. The substrate transfer robot 178 is configured to load and unload substrates, e.g., the substrate 2, from the chamber arrangement 104 and is this respect is coupled to the injection flange 158 by the gate valve 176. In further respect, the substrate transfer robot 178 may be operably associated with the controller 108 to load and unload substrates from the interior 144 of the chamber body 160 through the gate valve 176 and the injection flange 158.

It is contemplated that the chamber arrangement 104 include a divider 180, a support member 182, and a ceramic shaft 200. The divider 180 may be formed from an opaque material 184, for example a material opaque to electromagnetic radiation in an infrared waveband, and is seated within the interior 144 of the chamber body 160, and divide the interior 144 of the chamber body 160 into an upper chamber 186 and a lower chamber 188. It is further contemplated that the divider 180 define a divider aperture 190 therethrough, the divider aperture 190 fluidly coupling the upper chamber 186 to the lower chamber 188, and that the substrate support 114 be supported within the divider aperture 190 for rotation R about the rotation axis 116. The substrate support 114 may further be formed from the opaque material 184 and configured to seat thereon the substrate 2 during deposition of the material layer 4 onto the substrate 2. In certain examples the opaque material 184 forming either (or both) the divider 180 and the substrate support 114 may include (or consist of or consist essentially of) a ceramic material, such as silicon carbide. In accordance with certain examples, the opaque material 184 forming either (or both) the divider 180 and the substrate support 114 may include (or consist of or consist essentially of) a carbonaceous material. Non-limiting examples of suitable carbonaceous materials include pyrolytic carbon and graphite, which may be coated with a ceramic coating, such as a silicon carbide coating by way of example

The support member 182 may be formed from a transparent material, for example a material transparent to electromagnetic radiation in an infrared waveband, such as the ceramic material 168. The support member 182 may further be arranged along the rotation axis 116 and within the lower chamber 188 of the chamber body 160, and further be fixed in rotation R about the rotation axis 116 relative to the substrate support 114. The ceramic shaft 200 may be fixed in rotation R about the rotation axis 116 relative to the support member 182 and arranged along the rotation axis 116. The ceramic shaft 200 may further extend through a passthrough 192 defined within the lower wall of the chamber body 160 and into an annular gap 194 defined between the ceramic shaft 200 and a tubulation member 196 protruding from the lower wall of the chamber body 160 and extending about both the passthrough 192 and the ceramic shaft 200, the annular gap 194 providing fluid communication between the process fluid source 102 (shown in FIG. 1) and the lower chamber 188 of the chamber body 160, the annular gap 194 pneumatically sealed from the external environment by the lift and rotate assembly 1000. Advantageously, fluid coupling of the process fluid source 102 with the lower chamber 188 via the annular gap 194 enables providing additional precursor, for example the dopant-containing material layer precursor 146 (shown in FIG. 2), to edges of the substrate 2 during deposition of the material layer 4 onto the substrate 2 via the divider aperture 190, limiting cross-substrate material variation in processes affected by mass flow rate variation of certain material layer precursors.

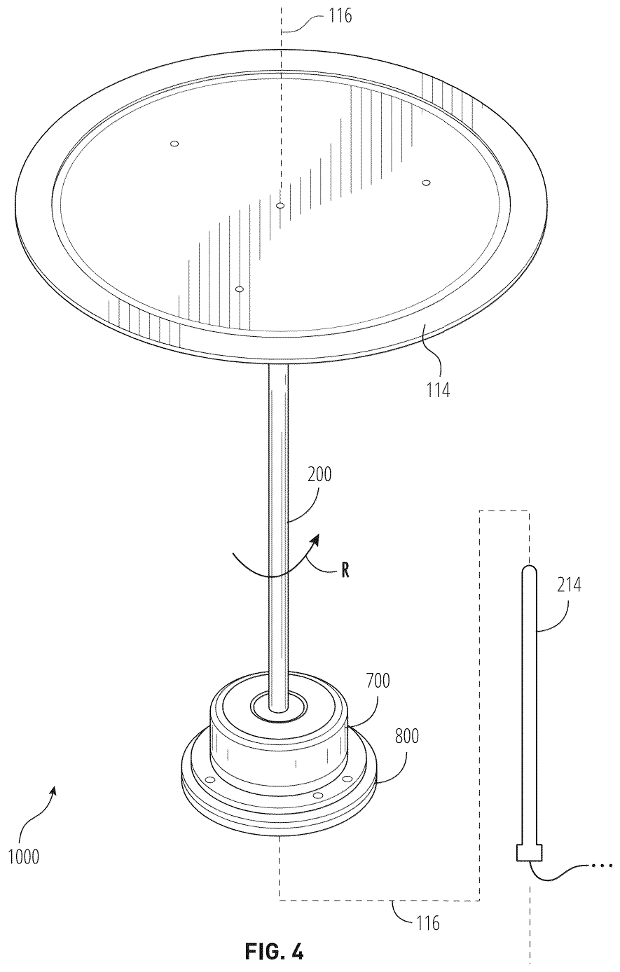

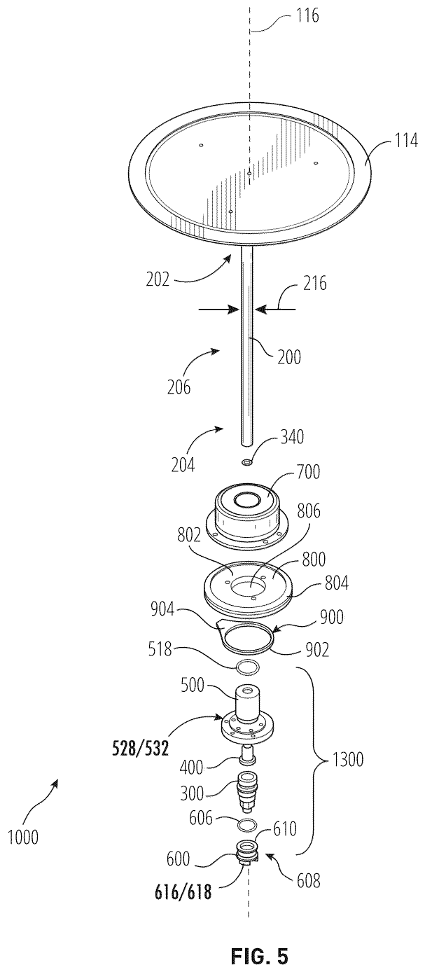

With reference to FIG. 4 to FIG. 7, the lift and rotate assembly 1000 is shown in an exploded view according to an example of the present disclosure. As shown in FIG. 4, the lift and rotate assembly 1000 includes the ceramic shaft 200, a shaft carrier 300 (shown in FIG. 5), a segmented sleeve 400 (shown in FIG. 5), a flanged sleeve 500 (shown in FIG. 5), and a cylindrical sleeve 600 (shown in FIG. 5). As shown and described herein the lift and rotate assembly 1000 also includes a bearing arrangement 700, a drive gear 800, and a flag structure 900 (shown in FIG. 5). Although shown and described herein as including certain elements it is to be understood and appreciated that the lift and rotate assembly 1000 may include other element and/or omit elements shown and described herein and remain within the scope of the present disclosure.

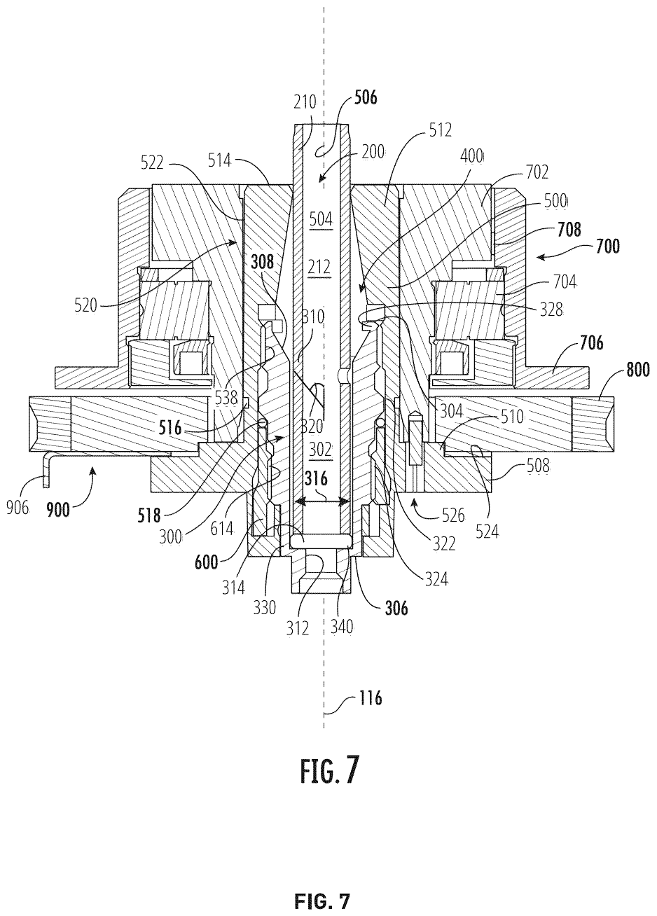

As shown in FIG. 5 and FIG. 7, the ceramic shaft 200 has a first end 202, a second end 204, and stem 206. The first end of the ceramic shaft 200 is arranged within the interior 144 (shown in FIG. 3) of the chamber body 160 (shown in FIG. 3). The stem 206 of the ceramic shaft 200 extends through the passthrough 192 defined in the lower wall of the chamber body 160, is disposed (at least in part) within the tubulation member 196 (shown in FIG. 3) extending about the passthrough defined in the chamber body 160 and protruding from the lower wall of the chamber body 160, and is separated from the tubulation member 196 by the annular gap 194 (shown in FIG. 3). The second end 204 of the ceramic shaft 200 is seated within the shaft carrier 300 and fixed therein by the segmented sleeve 400. It is contemplated that the ceramic shaft 200 be arranged along the rotation axis 116 and in this respect engagement of the segmented sleeve 400 about the stem 206 of the ceramic shaft 200, and in turn engagement of the shaft carrier 300 to the segmented sleeve 400, operates to align the ceramic shaft 200 to the rotation axis 116 to limit tilt 111 (shown in FIG. 3) and wobble 113 (shown in FIG. 3) of the substrate support 114 (shown in FIG. 3) during rotation R about the rotation axis 116. As will be appreciated by those of skill in the art in view of the present disclosure, limiting wobble and runout of the substrate support 114 during rotation R about the rotation axis 116 in turn may limit cross-substrate variation of material layer 4 (shown in FIG. 1) deposited onto the substrate 2) during rotation about the rotation axis 116.

In certain examples the ceramic shaft 200 may include (or consist of or consist essentially of) a ceramic material 210 (shown in FIG. 7). In this respect it is contemplated that the ceramic material 210 may be a transparent ceramic material, for example a ceramic material transparent to electromagnetic radiation within an infrared waveband, and may be as shown and described in U.S. Patent Application Publication No. 2024/0222187 A1, filed on Dec. 27, 2023, the contents of which is incorporated herein by reference in its entirety. Examples of suitable ceramic material include fused silica, quartz, and sapphire. In accordance with certain examples, the ceramic shaft 200 may define a bore 212 (shown in FIG. 7) therein, also referred to herein as the ceramic bore. In such examples the bore 212 may extend between the first end 202 and the second end 204 of the ceramic shaft 200. In such examples a probe member 214 (shown in FIG. 4) of a temperature sensor assembly (e.g., a thermocouple) may be arranged within the bore 212, the probe member 214 carried by the ceramic shaft 200 during rotation about the rotation axis 116, the probe member 214 protruding from either (or both) the first end 202 and the second end 204 of the ceramic shaft 200, for example to acquire temperature of the substrate 2 (shown in FIG. 1) via the substrate support 114 (shown in FIG. 1). It is also contemplated that the ceramic shaft 200 may be substantially solid in arrangement (e.g., include no central bore) and remain within the scope of the present disclosure.

The shaft carrier 300 is arranged along the rotation axis 116 and defines a bore 302 therethrough, also referred to herein as the shaft carrier bore. The bore 302 extends between chamber-facing surface 304 and an axially opposite castellated face 306 and extends about the rotation axis 116. The bore 302 further has a tapered segment 308, an intermediate segment 310, and a terminal segment 312. The tapered segment 308 of the bore 302 tapers in width between a relatively wide width proximate the chamber-facing surface 304 of the shaft carrier 300 to a relative narrow width proximate the intermediate segment 310 of the bore 302. The intermediate segment 310 of the bore 302 extends axially from tapered segment 308 of the bore 302, terminates at a shoulder 314, and has a width 316 that is greater than a width 216 (shown in FIG. 7) of the ceramic shaft 200. The terminal segment 312 of the bore extends axially from the intermediate segment 310 of the bore 302 to the castellated face 306 of the shaft carrier 300, is axially separated from the tapered segment 308 of the bore 302 by the intermediate segment 310 of the bore 302, and has a width 318 that is less than the width 216 of the ceramic shaft 200. It is contemplated that the tapered segment 308 of the bore 302 define a taper angle 320 relative to the rotation axis 116 therein selected to collapse the segmented sleeve 400 when the segmented sleeve is advance into the bore 302. In this respect it is contemplated that taper angle 320 differ from a nominal taper angle 402 (e.g., an uncompressed taper angle) defined by the segmented sleeve 400, and in this respect the taper angle 320 may be greater than or less than the nominal taper angle 402 of the segmented sleeve 400.

The shoulder 314 with the bore 302 is configured to seat thereon an inner resilient member 340 to axially space the second end 204 of the ceramic shaft 200 from the shoulder 314. In this respect the shoulder 314 may be substantially planar in contour. In further respect, the shoulder 314 may be substantially orthogonal relative to the rotation axis 116 in certain examples of the disclosure. It is further contemplated that the inner resilient member 340 may be captive between the first end 202 of the ceramic shaft 200 and the shoulder 314 defined within the bore 302 defined within the shaft carrier 300, and that the ceramic shaft 200 may be radially spaced apart from the shaft carrier 300 within the bore 302 as well as axially spaced from the shoulder 314 within the bore 302. As will be appreciated by those of skill in the art in view of the present disclosure, axially separating the ceramic shaft 200 from the shoulder 314 defined within the bore 302 of the shaft carrier 300 may limit risk of damage to the ceramic shaft 200 during assembly of the ceramic shaft 200 in the shaft carrier 300, improving reliability of the semiconductor processing system 100 (shown in FIG. 1).

It is contemplated that the shaft carrier 300 define a first male threaded segment 322, a second male threaded segment 324, and a land 326 on an exterior surface 330 of the shaft carrier 300. The first male threaded segment 322 is configured to threadedly seat the shaft carrier 300 within the flanged sleeve 500 and in this respect include male threads corresponding (e.g., in pitch and/or number) to female threads of a female threaded segment 502 defined within a bore 504 (also referred to herein as the flanged sleeve bore) extending through the flanged sleeve 500. The second male threaded segment 324 may be axially separated from the chamber-facing surface 304 of the shaft carrier 300 by the tapered segment 308 of the bore 302, and that land 326 in turn axially separate the first male threaded segment 322 from the castellated face 306 of the shaft carrier 300. The land 326 is configured to seat thereon an intermediate resilient member 518 to provide fluid separation between the annular gap 194 (shown in FIG. 3) defined between the ceramic shaft 200 and the tubulation member 196 (shown in FIG. 3), and may be oblique relative to the rotation axis 116.

In certain examples the second male threaded segment 324 may be axially separated from the first male threaded segment 322 by the land 326. The second male threaded segment 324 may be radially inward of the first male threaded segment 322 and in this respect may be radially between the first male threaded segment 322 and the rotation axis 116. In further respect, the second male threaded segment 324 may include (e.g., define) male threads corresponding to female threads of a female threaded segment 602 defined on an interior surface 604 of the cylindrical sleeve 600. The second male threaded segment 324 further axially separates the land 326 from the castellated face 306, the castellated face 306 in turn defining a plurality of castellations circumferentially distributed about the rotation axis 116 and configured to receive thereon a tool for rotating the shaft carrier 300 within the flanged sleeve 500 to collapse the segmented sleeve 400 onto the stem 206 of the ceramic shaft 200 according to exertion of a predetermined torque on the shaft carrier 300 relative to the flanged sleeve 500.

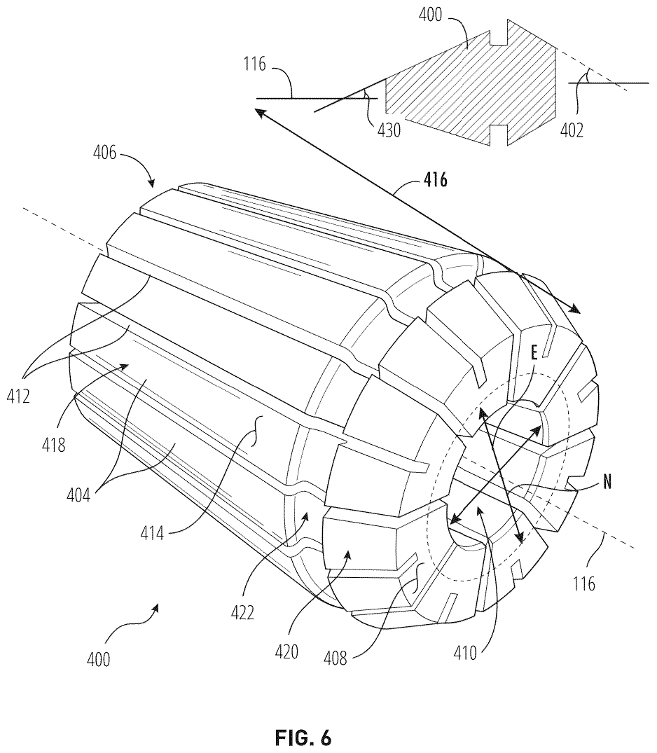

Referring to FIG. 6 and with continuing reference to FIG. 7, it is contemplated that the segmented sleeve 400 include a plurality of longitudinal segments 404 each extending between a chamber-facing surface 406 and a shoulder-facing surface 408. The plurality of longitudinal segments 404 may in turn be distributed circumferentially about the rotation axis 116, define a bore 410 (also referred to herein as the segmented sleeve bore) extending axially through the segmented sleeve 400 coupling the chamber-facing surface 406 and the shoulder-facing surface 408, and be separated from one another by a plurality of longitudinal slots 412. The plurality of longitudinal slots 412 may extend radially between an exterior surface 414 of the segmented sleeve 400 and the bore 410, fluidly couple the exterior surface 414 of the segmented sleeve 400 to the bore 410, and only partially span an axial length 416 of the segmented sleeve 400. In this respect it is contemplated two or more of the plurality of longitudinal slots 412 may circumferentially interrupt the chamber-facing surface 406 of the segmented sleeve 400 and terminate at a location axially intermediate the chamber-facing surface 406 and the shoulder-facing surface 408, two or more of the plurality of longitudinal slots 412 may circumferentially interrupt the shoulder-facing surface 408 of the segmented sleeve 400 and terminate at a location axially intermediate the shoulder-facing surface 408 and the chamber-facing surface 406, and that each of the latter circumferentially separate circumferentially pairs of the latter. As will be appreciated by those of skill in the art in view of the present disclosure, this imparts a radial spring constant to the segmented sleeve 400, enabling the segmented sleeve 400 to collapse about the ceramic shaft 200 in examples where a nominal width of the bore 410 extending through the segmented sleeve 400 is greater than the width 216 of the ceramic shaft 200.

It is contemplated that the segmented sleeve 400 have a major tapered portion 418 axially separated from a minor tapered portion 420 by a circumferential slot 422. The minor tapered portion 420 extends axially from the shoulder-facing surface 408 of the segmented sleeve 400 to the circumferential slot 422, has an axial length 424 that is less than an axial length 426 of the major tapered portion 418 of the segmented sleeve 400, and tapers between a relatively small width defined at the shoulder-facing surface 408 to a relatively large width defined proximate the circumferential slot 422. It is further contemplated that the minor tapered portion 420 of the segmented sleeve 400 be configured to be compressively seated in the tapered segment 308 of the bore 302 defined within the shaft carrier 300. In this respect it is contemplated that the minor tapered portion 420 define a nominal taper angle 402 (e.g., when the segmented sleeve 400 is not collapsed) relative to the rotation axis 116, and that the nominal taper angle 402 differ from the taper angle 320 defined by the tapered segment 308 of the bore 302 defined within the shaft carrier 300. In this respect the nominal taper angle 402 may be less than or greater than the taper angle 320. As will be appreciated by those of skill in the art in view of the present disclosure, this enables the minor tapered portion 420 of the segmented sleeve 400 to be received in the shaft carrier 300, for example for subsequent assembly of the shaft carrier 300 and the segmented sleeve 400 as a subassembly into the flanged sleeve 500.

The major tapered portion 418 of the segmented sleeve 400 extends axially from the circumferential slot 422 to the chamber-facing surface 406 of the segmented sleeve 400, is axially longer that the minor tapered portion 420 of the segmented sleeve 400, and tapers in width between a relative large width proximate the circumferential slot 422 to a relative small width proximate the chamber-facing surface 406 of the segmented sleeve 400. It is contemplated that the major tapered portion 418 define nominal taper angle 430 relative to the rotation axis 116 (e.g., when the segmented sleeve 400 is not collapsed), and that the nominal taper angle 430 differ from a taper angle 506 defined within a bore 504 of the flanged sleeve 500. In this respect it is contemplated that the nominal taper angle 428 be smaller than the taper angle 506, the major tapered portion 418 of the segmented sleeve 400 thereby collapsing when the segmented sleeve 400 is advanced into the bore 504 defined within the flanged sleeve 500. It is further contemplated that the major tapered portion 418 of the segmented sleeve 400 protrude axially from the shaft carrier 300 along the rotation axis 116, enabling further collapse of the segmented sleeve 400 by advancement of the shaft carrier 300 into the flanged sleeve 500.

The circumferential slot 422 extends circumferentially about the segmented sleeve 400, axially separates the major tapered portion 418 from the minor tapered portion 420 of the segmented sleeve 400, and may be configured to receive therein a flange portion 328 of the shaft carrier 300 extending radially inward at the chamber-facing surface 304 of the shaft carrier 300. It is contemplated that the flange portion 328 may extend eccentrically about the rotation axis 116 and/or define an opening into the tapered segment 308 of the bore 302 with an elliptical shape, the flange portion 328 cooperating with the circumferential slot to form a stripper feature, simplifying assembly and disassembly of the segmented sleeve 400 into the shaft carrier 300. In certain examples the flange portion 328 may protrude radially inward relative to the rotation axis 116 and occupy, only in part, the circumferential slot 422 extending about the segmented sleeve 400. As will be appreciated by those of skill in the art in view of the present disclosure, this may facilitate assembly and disassembly of the segmented sleeve 400 from the shaft carrier 300, limiting time required for servicing the semiconductor processing system 100 (shown in FIG. 1).

In certain examples of the present disclosure the segmented sleeve 400 may be formed as collet. In accordance with certain examples, the segmented sleeve 400 may conform in part to a nominal size ER 20 collet as described in ISO Standard No. 15488:2003(E). In this respect the bore 410 defined within the segmented sleeve 400 may be diametrically enlarged relative the nominal size ER 20 collet as described in ISO Standard No. 15488:2003(E), the contents of which is incorporated herein by reference in its entirety, as shown with reference letters E and N (shown in FIG. 4). Advantageously, diametrically enlarging the bore 410 relative the nominal size ER 20 collet as described in ISO Standard No. 15488:2003(E) reduces a spring constant of the segmented sleeve 400, deformation associated with thermal cycling of the segmented sleeve 400 and extending service life of the segmented sleeve 400 beyond that otherwise expected in applications wherein the segmented sleeve 400 is exposed to relatively high temperatures, for example between about 100 degrees Celsius and about 400 degrees Celsius.

In certain examples the segmented sleeve 400 may be formed from a stainless steel material. Examples of suitable stainless steel material include DIN 1.4122 stainless steel. Advantageously, forming the segmented sleeve 400 from such stainless steel materials may render the segmented sleeve corrosion resistant to materials inhabiting the interior 144 of the chamber body 160. For example, forming the segmented sleeve 400 from a stainless steel material such as DIN 1.4122 may limit corrosion otherwise associated with contact with a material layer precursor like phosphine (P₂H₄) and arsine (AsH₃) as well as hydrogen (H₂) gas (in greater-than atmospheric concentrations) and hydrochloric (HCl) that may infiltrate the segmented sleeve 400 (and/or the annular gap 194) via the ceramic shaft 200 from the interior 144 of the chamber body 160. As will be appreciated by those of skill in the art in view of the present disclosure, this can simplifying sealing of the annular gap 194 (shown in FIG. 3) defined between the tubulation member 196 (shown in FIG. 3) and the ceramic shaft 200 and/or improve reliability of the semiconductor processing system 100 (shown in FIG. 1).

With continuing reference to FIG. 5 and further reference to FIG. 7, it is contemplated that the flanged sleeve 500 define the rotation axis 116 and may be configured to seat therein both the shaft carrier 300 and the segmented sleeve 400. In this respect the flanged sleeve 500 defines the bore 504 therethrough and has a flange portion 508, a stepped or necked portion 510, and a stem portion 512. The stem portion 512 of the flanged sleeve 500 has a chamber-facing surface 514 that is substantially orthogonal relative to the rotation axis 116, axially opposes the chamber body 160 (shown in FIG. 3), and which extends circumferentially about the rotation axis 116. The stepped or necked portion 510 of the flanged sleeve 500 is axially intermediate the stem portion 512 and the flange portion 508 of the flanged sleeve 500. It is contemplated that the stepped or necked portion 510 may be configured to seat thereabout 9at least in part) the drive gear 800 for rotating the substrate support 114 (shown in FIG. 3) about the rotation axis 116. The stepped or necked portion 510 may further be configured to seat there the flag structure 900, enabling seating and unseating the substrate 2 (shown in FIG. 1) from the substrate support 114 (shown in FIG. 1) using lift pins carried by the substrate support 114 using a lift pin actuator fixed in rotation about the ceramic shaft 200 relative to the chamber body 160 (shown in FIG. 3). It is contemplated that the flanged sleeve 500 be configured for fluid sealing between the annular gap defined between the tubulation member 196 (shown in FIG. 3) and the ceramic shaft 200. In this respect the stepped or necked portion 510 of the flanged sleeve 500 may define a sealing groove configured to seat therein an intermediate resilient member 518, the intermediate resilient member 518 in turn pneumatically sealing a gap 520 defined between an exterior surface 522 of the flanged sleeve 500 and the bearing arrangement 700.

The flange portion 508 of the flanged sleeve 500 is axially separated from the stem portion 512 of the flanged sleeve 500 along the rotation axis 116 by the stepped or necked portion 510 of the flanged sleeve 500. The flange portion 508 further extends circumferentially about the rotation axis 116 and radially from the stepped or necked portion 510 of the flanged sleeve 500, and has a chamber-facing surface 524 and an axially opposite flange portion face 526. It is contemplated that the chamber-facing surface 524 define therein a fastener pattern 528, and that the drive gear 800 and/or the flag structure 900 be fixed to the flange portion 508 of the flanged sleeve 500 by a plurality of fasteners threadedly received in the fastener pattern 528. Is also contemplated that the flange portion face 526 may define therein a through-hole pattern 532 extending through the stepped or necked portion 510 of the flanged sleeve 500, and that a stator 706 of the bearing arrangement 700 extending about the stem portion 512 of the flanged sleeve 500 may be fixed to the flanged sleeve 500 through fasteners extending through the through-hole pattern 532.

In certain examples the bearing arrangement 700 may include a rotor 702, a bearing body 704, the stator 706, and a ferrofluidic seal 708. The rotor 702 may extend about the stem portion 512 of the flanged sleeve 500 and be fastened to the flange portion 508 of the flanged sleeve 500 via the through-hole pattern 532. The stator 706 may extend about the rotor 702 and be coupled to the rotor 702 by the bearing body 704, which may include a thrust bearing or a cross bearing, the stator 706 and the rotor 702 radially overlapping the shaft carrier 300 in certain examples of the present disclosure. The ferrofluidic seal 708 may be radially intermediate the stator 706 and the rotor 702, for example in an axial gap defined therebetween, the ferrofluidic seal 708 fluidly separating the ceramic shaft 200, and more particularly the annular gap 194 (shown in FIG. 3) inhabited by the ceramic shaft 200 and fluidly coupled to the interior 144 (shown in FIG. 3) of the chamber body 160 (shown in FIG. 3) from the external environment 10 outside the lift and rotate assembly 1000. Advantageously, including of the bearing arrangement 700 as described herein may limit size of the lift and rotate assembly 1000, enabling upgrade of certain legacy semiconductor processing systems using a tilt and wobble kit 1300 (shown in FIG. 5).

In certain examples the drive gear 800 may be fixed to the flange portion 508 flanged sleeve 500 at the fastener pattern 528. In this respect the drive gear 800 may include an annular web portion 802 with through-holes defined therethrough corresponding to the fastener pattern 528 and toothed periphery 804 extending about the annular web portion 802 of the drive gear 800. It is further contemplated that the annular web portion 802 may define a drive gear aperture 806 therethrough, and that the drive gear 800 may further receive the stem portion 512 of the flanged sleeve 500 therethrough such that the drive gear 800 extends about the stator 706 of the bearing arrangement 700 is fastened to the flange portion 508 of the flanged sleeve 500.

In certain examples the flag structure 900 may be seated on the flange portion 508 of the flanged sleeve 500. In this respect the flag structure 900 may have an annular portion 902, a tang portion 904, and a flag portion 906. The annular portion 902 may extend circumferentially about the stepped or necked portion 510 of the flanged sleeve 500. The tang portion 904 of the flag structure 900 may extend radially from the annular portion 902 of the flag structure 900, and the flag portion 906 may extend axially from the tang portion 904 of the flag structure 900. It is contemplated that the flag structure 900 may be fastened to the flange portion 508 of the flanged sleeve 500. It is also contemplated that the flag portion 906 may be compressively fixed to the flange portion 508, for example by axial stacking of the flag structure 900 either (or both) the drive gear 800 and the bearing arrangement 700 such that the flag structure 900 is axially intermediate either (or both) the drive gear 800 or the bearing arrangement 700 and the flange portion 508 of the flanged sleeve 500. As will be appreciated by those of skill in the art in view of the present disclosure, this can limit part count of the lift and rotate assembly 1000, limiting cost and complexity of the lift and rotate assembly 1000.

The bore 504 defined within the flanged sleeve 500 extends about the rotation axis 116 and axially between the chamber-facing surface 524 and the flange portion face 526 of the flanged sleeve 500. It is contemplated that the bore 504 have a tapered segment 536, a female threaded segment 538, and a fixed width segment 540. The tapered segment 536 of the bore 504 is configured to receive therein the segmented sleeve 400 and in this respect defines the taper angle 506. It is contemplated that the taper angle 506 may be greater than a nominal taper angle (e.g., an uncompressed taper angle) of the segmented sleeve 400. It is also contemplated that the taper angle 506 be defined within the stem portion 512 of the flanged sleeve 500 and narrow in width from a relatively narrow width proximate the chamber-facing surface 524 and a relative width proximate the stepped or necked portion 510 of the flanged sleeve 500.

The female threaded segment 538 of the bore 504 is configured to threadedly receive male threads of the first male threaded segment 322 defined on the exterior surface 330 of the shaft carrier 300. It is further contemplated that the female threaded segment 538 of the bore 504 further be axially intermediate the tapered segment 536 and the fixed width segment 540 of the bore 504, and that the female threaded segment 538 be defined within the stem portion 512 of the flanged sleeve 500. The fixed width segment 540 of the bore 504 is configured to receive therein (at least in part) the cylindrical sleeve 600 and in this respect may extend between the female threaded segment 502 defined within the bore 504 of the flanged sleeve 500 and the flange portion face 526 of the flange portion 508 of the flanged sleeve 500. It is contemplated that the taper angle 506 of the tapered segment 536 of the bore 504 cooperate with threads of the female threaded segment 502 and the major taper angle of the segmented sleeve 400 such that threaded advancement of the shaft carrier 300 into the flanged sleeve 500 collapses the segmented sleeve 400 to a diameter substantially equivalent to that of the ceramic shaft 200.

The cylindrical sleeve 600 is configured to seal the bore 504 defined within the flanged sleeve 500 using the intermediate resilient member 518 and in this respect has a cylindrical body 608 with a chamber-facing surface 610, an interior surface 612 with a female threaded segment 614, and an end face 616 with a plurality of castellations 618. The chamber-facing surface 610 extends circumferentially about the rotation axis 116, conforms diametrically (e.g., is substantially equivalent) to a diameter of the intermediate resilient member 606 when the intermediate resilient member 606 is positioned on the land of the shaft carrier 300, and may be substantially orthogonal relative to the rotation axis 116. The female threaded segment 614 defined on the interior surface 612 corresponds to the second male threaded segment 324 defined on the exterior surface 330 of the shaft carrier 300, and is configured to axially advance the cylindrical sleeve 600 relative to the shaft carrier 300 when the cylindrical sleeve 600 is threadedly engaged to the second male threaded segment 324 defined on the exterior surface 330 of the shaft carrier 300 and rotated about the rotation axis 116 relative to the shaft carrier 300.

The end face 616 of the cylindrical sleeve 600 is axially separated from the from the chamber-facing surface 610 of the cylindrical sleeve 600 by the female threaded segment 602 defined on the interior surface 612 of the cylindrical sleeve 600, and is configured for engagement by a tool through the plurality of castellations 618. It is contemplated that the cylindrical sleeve 600 seal the bore 504 defined within the flanged sleeve 500 by compressive fixing the intermediate resilient member 606 between the fixed width segment 540 of the bore 504 defined within the flanged sleeve 500 and the land 326 defined on the exterior surface 330 of the shaft carrier 300.

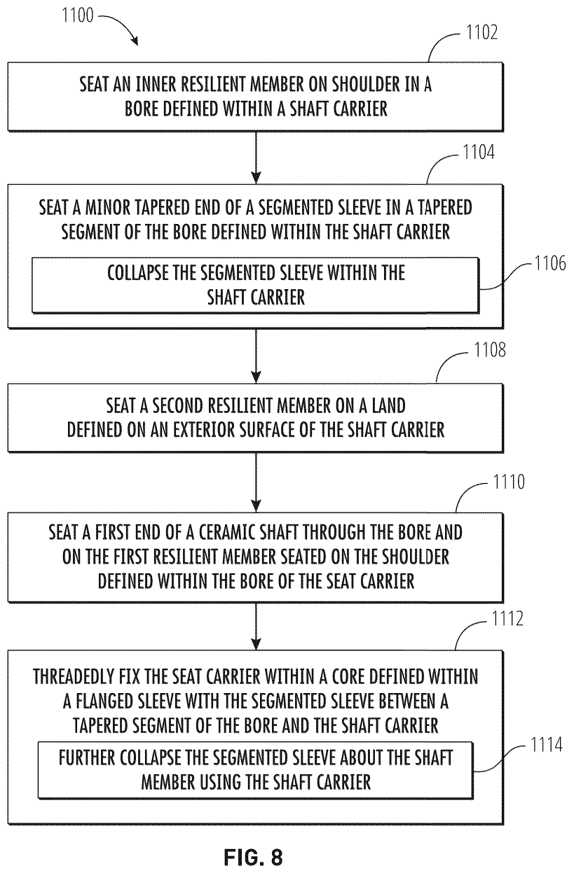

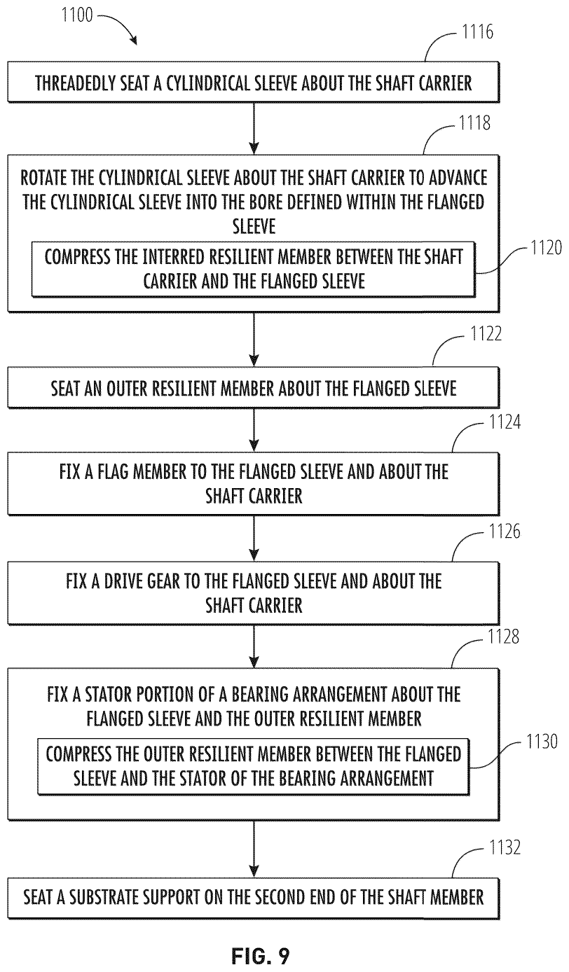

With reference to FIG. 8 and FIG. 9, a method 1100 of making a lift and rotate assembly, e.g., the lift and rotate assembly 1000 (shown in FIG. 1), is shown. Referring to FIG. 8, the method 1100 includes seating an inner resilient member on a shoulder defined within a bore of a shaft carrier, e.g., the inner resilient member 340 (shown in FIG. 5) on the shoulder 314 (shown in FIG. 5), as shown with box 1102. The method 1100 also includes seating a minor tapered portion of a segmented sleeve in a tapered segment of the bore defined within the shaft carrier, e.g., the minor tapered portion 420 (shown in FIG. 6) of the segmented sleeve 400 (shown in FIG. 5) with the bore 302 (shown in FIG. 7) of the shaft carrier 300 (shown in FIG. 7), as shown with box 1104. It is contemplated that seating the minor tapered portion of the segmented sleeve in the tapered segment of the bore defined in the shaft carrier may include collapsing the segmented sleeve within the shaft carrier, for example such that a bore defined within the shaft carrier has a width that is smaller than a nominal width of the shaft carrier and greater than a width a ceramic shaft, as shown with box 1106. It also contemplated that the degree of collapse may be control by the radial extent of a flange portion of the shaft carrier extending into the bore and received within a circumferential slot defined within an exterior surface of the segmented sleeve, as also shown with box 1106.

As shown with box 1108, an intermediate resilient member may be seated at least in part on a land defined on an exterior surface of the shaft carrier, for example the intermediate resilient member 518 (shown in FIG. 5) seated on the land 326 (shown in FIG. 7) defined on the exterior surface 330 (shown in FIG. 7) of the shaft carrier. As shown with box 1110, a first end of the ceramic shaft may be seated within the bore defined within the shaft carrier by sliding the ceramic shaft through the segmented sleeve such that the first end of the ceramic shaft abuts the inner resilient member, for example such that the first end of the ceramic shaft is separated from the shoulder defined within the bore by the inner resilient member. The shaft carrier may then be threadedly fixed within a bore defined within a flanged sleeve, e.g., the bore 504 (shown in FIG. 7) of the flanged sleeve 500 (shown in FIG. 7), using female threads of a female threaded segment defined within the bore of the flanged sleeve, e.g., the female threaded segment 538 (shown in FIG. 7), as shown with box 1112, and the segmented sleeve further collapsed by advancement of the shaft carrier and the segmented sleeve seated thereon into the bore defined within the flanged sleeve by operation of the threaded engagement of the shaft carrier within the flange portion, as shown with box 1114. It is contemplated that the further collapse cause the segmented sleeve to become fixed to a stem of the ceramic shaft, the ceramic shaft thereby aligned to a rotation axis defined by the flanged sleeve such that runout and wobble of a substrate support carried by the lift and rotate assembly is limited during rotation about the rotation axis, as also shown with box 1114.

Referring to FIG. 9, the method 1100 may further include seating a cylindrical sleeve about the shaft carrier, e.g., the cylindrical sleeve 600 (shown in FIG. 5), as shown with box 1116. The cylindrical sleeve may be threadedly seated about the shaft carrier, and the cylindrical sleeve may be rotated relative to the shaft carrier such that cylindrical shaft advances into the bore defined within the flanged sleeve relative to the shaft carrier, as shown with box 1118. It is contemplated that advancement of the cylindrical sleeve into the bore defined within the flanged sleeve compress the intermediate resilient member seated on the shaft carrier, as shown with box 1120. The compressive forced exerted on the intermediate resilient member may be such that the intermediate resilient member fluidly separates an annular gap defined between a tubulation member extending about the ceramic shaft and an external environment outside of the tubulation member, e.g., the annular gap 194 (shown in FIG. 3) defined between the tubulation member 196 (shown in FIG. 3) and the ceramic shaft, as also shown with box 1120.

It is contemplated that an outer resilient member may be seated about the flanged sleeve, e.g., the outer resilient member 516 (shown in FIG. 5), about the flanged member, as shown with box 1122. A flag structure may be fixed to the flanged sleeve, e.g., the flag structure 900 (shown in FIG. 5), and a drive gear further fixed to the flanged member, e.g., the drive gear 800 (shown in FIG. 5), as shown with box 1124 and box 1126. The flanged sleeve may then be affixed to a stator of a bearing arrangement, e.g., the stator 706 (shown in FIG. 5) of the bearing arrangement 700 (shown in FIG. 5), using a plurality of fasteners slidably received in through-holes extending through the flanged sleeve, as shown with box 1128. It is contemplated that fixation of the flanged sleeve to the stator of the bearing arrangement may compress the outer resilient member between the flanged sleeve and the stator of the bearing arrangement, fluidly sealing a leakage path defined between the annular gap defined between the ceramic shaft and tubulation member, as shown with box 1130. A substrate support may thereafter be coupled to the second end of the ceramic shaft, e.g., the substrate support 114 (shown in FIG. 1), the substrate support thereby supported for rotation about the rotation axis defined by the flanged sleeve by the ceramic shaft, the segmented sleeve, and shaft carrier, as shown with box 1132.

With reference to FIG. 10, a material layer deposition method 1200 is shown. The method 1200 includes seating a substrate on a substrate support carried by the ceramic shaft, e.g., the substrate 2 (shown in FIG. 1) on the substrate support 114 (shown in FIG. 1) carried by the ceramic shaft 200 (shown in FIG. 3), as shown by box 1210. The substrate and the substrate support are rotated about a rotation axis using rotation communicated through a segmented sleeve fixed to the ceramic shaft, e.g., the segmented sleeve 400 (shown in FIG. 5), as shown with box 1220. The substrate is further heated to a predetermined material layer deposition temperature and the substrate contacted with a process fluid, e.g., the process fluid 110 (shown in FIG. 1), as shown with box 1230 and box 1240. It is contemplated that a material layer be deposited onto the substrate and/or that material be removed from the substrate using the process fluid, as shown with box 1250 and box 1260, and that tilt and wobble of the substrate support carried by the ceramic shaft during rotation about the rotation axis is limited by compressive fixation and radial collapse of the segmented sleeve about the ceramic shaft, as also shown with box 1250 and box 1260. In certain examples the process fluid may include a silicon-containing material layer precursor, e.g., the silicon-containing material layer precursor 138 (shown in FIG. 2), as shown with box 1242. In accordance with certain examples, the process fluid may include a germanium-containing material layer precursor, e.g., the germanium-containing material layer precursor 140 (shown in FIG. 2), as shown with box 1244. It is also contemplated that the process fluid may include a dopant-containing material layer precursor and/or an etchant, e.g., the dopant-containing material layer precursor 146 (shown in FIG. 2) and/or the etchant 150 (shown in FIG. 2), as shown with box 1246 and box 1248. It is further contemplated that the process fluid may include a purge/carrier fluid, e.g., the carrier/purge fluid 154 (shown in FIG. 2), as shown with box 1241.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A lift and rotate assembly, comprising:
a shaft carrier defining a shaft carrier bore therethrough;
a ceramic shaft received within the shaft carrier bore;
a segmented sleeve seated in the shaft carrier and extending about the ceramic shaft; and
a flanged sleeve defining a rotation axis and threadedly receiving therein the shaft carrier, wherein the segmented sleeve is compressively fixed and radially collapsed about the ceramic shaft within the shaft carrier bore of the shaft carrier to limit tilt and wobble of a substrate support carried by the ceramic shaft during rotation about the rotation axis.

2. The lift and rotate assembly of claim 1, wherein the shaft carrier bore has a tapered segment and a shoulder defined therein, wherein a first end of the ceramic shaft is axially spaced apart from the shoulder within the shaft carrier bore.

3. The lift and rotate assembly of claim 2, further comprising an inner resilient member axially separating the ceramic shaft from the shoulder, the inner resilient member captive between the first end of the ceramic shaft and the shoulder.

4. The lift and rotate assembly of claim 2, wherein the shaft carrier defines a first male threaded segment and a second male threaded segment on an exterior surface of the shaft carrier, the first male threaded segment axially separating the second male threaded segment from the first male threaded segment, the second male threaded segment radially between the first male threaded segment and the rotation axis.

5. The lift and rotate assembly of claim 1, wherein the ceramic shaft is formed from one of fused silica, quartz, and sapphire, wherein the ceramic shaft defines a ceramic bore therethrough, and further comprising a probe member of a temperature sensor slidably received within the ceramic bore and protruding from both a first end and a second end of the ceramic shaft.

6. The lift and rotate assembly of claim 1, wherein the ceramic shaft is radially spaced apart from the shaft carrier within the shaft carrier bore defined within the shaft carrier, wherein the ceramic shaft is axially spaced apart from a shoulder defined within the shaft carrier bore of the shaft carrier.

7. The lift and rotate assembly of claim 1, wherein the segmented sleeve has a minor tapered portion and a major tapered portion, the minor tapered portion received within the shaft carrier, the major tapered portion protruding axially from the shaft carrier.

8. The lift and rotate assembly of claim 7, wherein the minor tapered portion has a nominal taper angle that is different than taper of the shaft carrier bore defined within the shaft carrier to collapse the segmented sleeve to a width greater than that of the ceramic shaft, and wherein major tapered portion has a nominal tapered angle that is different than taper of a flanged sleeve bore defined within the flanged sleeve to further collapse the segment sleeve to a width substantially equivalent to that of the ceramic shaft.

9. The lift and rotate assembly of claim 7, wherein the segmented sleeve defines a circumferential slot extending about the segmented sleeve and axially separating the minor tapered portion of the segmented sleeve from the major tapered portion of the segmented sleeve, and wherein the shaft carrier has a flange portion protruding radially inward and occupying only in part the circumferential slot.

10. The lift and rotate assembly of claim 1, wherein the segmented sleeve conforms to a nominal size ER20 collet as described in ISO Standard No. 15488:2003(E), and wherein the segmented sleeve defines a segmented sleeve bore therethrough that is diametrically enlarged relative the nominal size ER 20 collet as described in ISO Standard No. 15488:2003(E).

11. The lift and rotate assembly of claim 1, wherein the segmented sleeve is formed from DIN 1.4122 stainless steel, and further comprising a fluid selected from the group consisting of phosphine (P₂H₄), arsine (AsH₃), hydrogen (H₂) gas, and hydrochloric (HCl) acid contacting the segmented sleeve.

12. The lift and rotate assembly claim 1, wherein the flanged sleeve has a stem portion, an axially opposite flange portion, and a stepped portion or a necked portion axially intermediate the stem portion and the flange portion of the flanged sleeve.

13. The lift and rotate assembly of claim 12, wherein the flanged sleeve defines a flanged sleeve bore therethrough having a tapered segment and a fixed width segment, wherein the stem portion of the flanged sleeve radially overlaps the tapered segment of the flanged sleeve bore, wherein flange portion of the flanged sleeve radially overlaps the fixed width segment of the flanged sleeve bore, and wherein a major tapered portion of the segmented sleeve is compressively seated within the tapered segment of the flanged sleeve bore.

14. The lift and rotate assembly of claim 12, further comprising a cylindrical sleeve threadedly received about the shaft carrier and arranged at least in part within a flanged sleeve bore defined within the flange portion of the flanged sleeve.

15. The lift and rotate assembly of claim 12, further comprising:
a flag structure extending about the stem portion of the flanged sleeve; and
a drive gear extending about the stem portion of the flanged sleeve and fastened to the flange portion of the flanged sleeve, wherein the flag structure is axially intermediate the drive gear and the flange portion of the flanged sleeve.

16. The lift and rotate assembly of claim 12, further comprising:
a bearing arrangement including:
a rotor extending about the stem portion of the flanged sleeve; and fastened to the flange portion of the flanged sleeve;
a stator extending about the rotor and coupled thereto by a bearing body; and
a ferrofluidic seal intermediate the stator and the rotor fluidly separating the ceramic shaft from an environment external to the lift and rotate assembly; and
a drive gear extending about the stator and fastened to the flange portion of the flanged sleeve, wherein the stator and the rotor radially overlap the shaft carrier.

17. The lift and rotate assembly of claim 1, wherein the shaft carrier has a castellated face protruding from the flanged sleeve, and further comprising a cylindrical sleeve extending about the shaft carrier and having a castellated face protruding from the flanged sleeve, the castellated face of the cylindrical sleeve extending about the castellated face of the shaft carrier, the cylindrical sleeve rotational free relative to the shaft carrier.

18. A semiconductor processing system, comprising:
a chamber arrangement including:
a chamber body with a tubulation member protruding therefrom;
an injection flange abutting an injection end of the chamber body; and
a substrate support supported for rotation within a interior of the chamber body by a lift and rotate assembly as recited in claim 1, the ceramic shaft of the lift and rotate assembly extending through the tubulation member and carrying the substrate support; and
a dopant-containing precursor source coupled to the injection flange by both a supply conduit and the tubulation member by a dopant-containing precursor source-to-tubulation member conduit.

19. A method of making a lift and rotate assembly, comprising:
seating an inner resilient member on a shoulder in a shaft carrier bore defined within a shaft carrier;
seating a minor tapered portion of a segmented sleeve in a tapered segment of the shaft carrier bore defined within the shaft carrier;
seating a first end of a ceramic shaft in the shaft carrier bore and on the inner resilient member seated on the shoulder and within shaft carrier bore; and
threadedly fixing the shaft carrier in a flanged sleeve bore defined within a flanged sleeve such that the ceramic shaft protrudes from the shaft carrier along a rotation axis defined by the flanged sleeve,
whereby seating the segmented sleeve in the shaft carrier collapses the segmented sleeve,
whereby threadedly fixing the shaft carrier in the flanged sleeve bore further collapses the segmented sleeve such the segmented sleeve is compressively fixed and radially collapsed about the ceramic shaft within the shaft carrier bore of the shaft carrier to limit tilt and wobble of a substrate support carried by the ceramic shaft during rotation about the rotation axis 20. A material layer deposition method, comprising:
at a lift and rotate assembly including a shaft carrier defining a shaft carrier bore therethrough, a ceramic shaft received within the shaft carrier bore, a segmented sleeve seated in the shaft carrier and extending about the ceramic shaft, and a flanged sleeve defining a rotation axis and threadedly receiving therein the shaft carrier, the segmented sleeve compressively fixed and radially collapsed about the ceramic shaft within shaft carrier bore of the shaft carrier,
seating a substrate on a substrate support carried by the ceramic shaft;
rotating the substrate support about the rotation axis;
contacting the substrate with a process fluid to at least one of deposit a material layer onto the substrate and remove material from the substrate; and
whereby tilt and wobble of the substrate support carried by the ceramic shaft during rotation about the rotation axis is limited by compressive fixation and radial collapse of the segmented sleeve about the ceramic shaft.
